(19) United States
(12) Patent Application Publication
(10) Pub. No.: US 2026/0311789 A1
(43) Pub. Date: Oct. 8, 2026

(54) Reading and Writing Device Under Test Register Values

(71) Applicant: NATIONAL INSTRUMENTS CORPORATION, Austin, TX (US)

(72) Inventors: Madras Sundararajan Mohanasundaram, Coppell, TX (US); Juan Carlos Contreras Santiago, Austin, TX (US)

(21) Appl. No.: 19/172,350

(22) Filed: Apr. 7, 2025

(51) Int. Cl. G11C 29/10

(52) U.S. Cl. CPC G11C 29/10

(57) ABSTRACT

Apparatuses, systems, and methods for reading/writing register values to a register of a device under test (DUT). A register-map and write template pattern/read template pattern of a DUT can be leveraged to generate a digital pattern that can be used to write specified values to specified fields and/or to verify that specified fields have specific values. Registers and/or register fields (e.g., a combination of bits in one or more registers) and corresponding values can be specified and combined with an associated register-map and write template pattern/read template pattern to generate an output pattern. The output pattern can then be deployed to the DUT to set values of specified registers and/or register fields or used to verify values of specified registers and/or register fields of the DUT via a comparison of the output pattern to bit values read from specified registers and/or register fields of the DUT.

### TECHNICAL FIELD

The invention relates to production and validation testing, and more particularly to apparatuses, systems, and methods for reading and writing register values to a register of a device under test (DUT).

### Description of the Related Art

Currently, writing values to device under test (DUT) registers is a common requirement in semiconductor and other production and validation tests. Generally, this is achieved by hand-coding digital patterns and waveforms to write specified values to specific registers based on a protocol supported by the DUT. Hand-coding digital patterns and waveforms for each DUT and for each set of registers of each DUT can be cumbersome, error-prone, and difficult to debug.

In some cases, a digital pattern editor (DPE), e.g., a software environment that allows users to interact with digital instruments, can include or support a mechanism to allow a user to define a DUT's register-map. The DPE can also be used by a user to read register values as well as to write register value to the DUT's registers using popular protocols such as inter-integrated circuit (I2C), serial peripheral interface (SPI), radio frequency front end Mobile Industry Processor Interface (RFFE-MIPI), and so forth. In addition, the DPE can be used to communicate with DUTs that use their own custom protocols. Such communications within the DPE can be achieved using template digital patterns to read from and write to the DUT’s registers. However, even using such templates, often defined and created by digital engineers conversant with the DUT's communication protocol can be cumbersome, error-prone, and difficult to deploy and debug. . Therefore, improvements are desirable.

### SUMMARY

Embodiments described herein relate to production and validation testing, and more particularly to apparatuses, systems, and methods for reading and writing register values to a register of a device under test (DUT).

For example, in some embodiments, a register-map and write template pattern of a DUT can be leveraged to generate a digital pattern that can be used to write specified values to specified fields and/or to verify that specified fields have specific values. In some instances, registers and/or register fields (e.g., a combination of bits in one or more registers) and corresponding values can be specified, e.g., in a table-view of the registers and/or register fields presented via a UI. Further, the specified registers and/or register fields and corresponding values can be combined with an associated register-map and write template pattern to generate an output pattern. The output pattern can then be deployed to the DUT, e.g., to set values of specified registers and/or register fields. Additionally, and/or alternatively, the output pattern can then be used to verify values of specified registers and/or register fields of the DUT, e.g., via a comparison of the output pattern to bit values read from specified registers and/or register fields of the DUT.

As another example, in some embodiments, a system can receive at least one input value for a register or register field of a DUT. The at least one input value can include a plurality of input values, where each input value is associated with a register or register field of a DUT. In addition, the at least one input value can be an array that includes one or more fields (e.g., such as a type field, a name field, a format field, and/or a value field). The system can generate an output pattern, e.g., based on the at least one input value. Further, the output pattern can be based on a register-map and read template pattern associated with the DUT.

As a further example, in some embodiments, upon generating the output pattern, a system can then write (or deploy) the output pattern to a DUT. Writing (or deploying) the output pattern can include sending the output pattern to the DUT over a communication connection with the DUT and/or via a relaying system (e.g., such as an embedded system in communication with the system and the DUT).

As yet a further example, in some embodiments, upon generating the output pattern, a system can read a register and/or register field of a DUT corresponding to the output pattern. Reading the register(s) and/or register field(s) can include reading bits of the register(s) and/or register field(s). Further, the system can compare the output pattern to the read register(s) and/or register field(s), e.g., to confirm and/or verify values of the register(s) and/or register field(s).

Note that the techniques described herein can be implemented in and/or used with a number of different types of devices, including but not limited to cellular phones, tablet computers, wearable computing devices, portable computing devices, portable media players, and any of various other computing devices.

This Summary is intended to provide a brief overview of some of the subject matter described in this document. Accordingly, it will be appreciated that the above-described features are only examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

A better understanding of the disclosed embodiments can be obtained when the following detailed description of the preferred embodiments is considered in conjunction with the following drawings.

FIG. 1 illustrates an example of a computer system, according to some embodiments.

FIG. 2 illustrates an example block diagram of a server 104, according to some embodiments.

FIGS. 3A and 3B illustrate examples of possible user interfaces for specifying values to generate an output pattern, according to some embodiments.

FIG. 4 illustrates a block diagram of an example of a method for DUT register pattern generation, according to some embodiments.

FIG. 5 illustrates a block diagram of an example of a method for writing a generated DUT register pattern to a DUT, according to some embodiments.

FIG. 6 illustrates a block diagram of an example of a method for verifying a DUT register pattern, according to some embodiments.

While the features described herein can be susceptible to various modifications and alternative forms, specific embodiments thereof are shown by way of example in the drawings and are herein described in detail. It should be understood, however, that the drawings and detailed description thereto are not intended to be limiting to the particular form disclosed, but on the contrary, the intention is to cover all modifications, equivalents and alternatives falling within the spirit and scope of the subject matter as defined by the appended claims.

### DETAILED DESCRIPTION

### Acronyms

Various acronyms are used throughout the present disclosure. Definitions of the most prominently used acronyms that can appear throughout the present disclosure are provided below:
DUT: Device Under Test
UUT: Unit Under Test
VI: Virtual Instrument
UI: User Interface
GUI:Graphical User Interface

### Terms

The following is a glossary of terms used in this disclosure:

Device Under Test (DUT) or Unit Under Test (UUT) – A physical device or component that is being tested.

Memory Medium – Any of various types of non-transitory memory devices or storage devices. The term “memory medium” is intended to include an installation medium, e.g., a CD-ROM, floppy disks, or tape device; a computer system memory or random-access memory such as DRAM, DDR RAM, SRAM, EDO RAM, Rambus RAM, etc.; a non-volatile memory such as a Flash, magnetic media, e.g., a hard drive, or optical storage; registers, or other similar types of memory elements, etc. The memory medium can include other types of non-transitory memory as well or combinations thereof. In addition, the memory medium can be located in a first computer system in which the programs are executed, or can be located in a second different computer system which connects to the first computer system over a network, such as the Internet. In the latter instance, the second computer system can provide program instructions to the first computer for execution. The term “memory medium” can include two or more memory mediums which can reside in different locations, e.g., in different computer systems that are connected over a network. The memory medium can store program instructions (e.g., embodied as computer programs) that can be executed by one or more processors.

Carrier Medium – a memory medium as described above, as well as a physical transmission medium, such as a bus, network, and/or other physical transmission medium that conveys signals such as electrical, electromagnetic, or digital signals.

Programmable Hardware Element – includes various hardware devices comprising multiple programmable function blocks connected via a programmable interconnect. Examples include FPGAs (Field Programmable Gate Arrays), PLDs (Programmable Logic Devices), FPOAs (Field Programmable Object Arrays), and CPLDs (Complex PLDs). The programmable function blocks can range from fine grained (combinatorial logic or look up tables) to coarse grained (arithmetic logic units or processor cores). A programmable hardware element can also be referred to as “reconfigurable logic”.

Computer System (or Computer) – any of various types of computing or processing systems, including a personal computer system (PC), mainframe computer system, workstation, network appliance, Internet appliance, personal digital assistant (PDA), television system, grid computing system, or other device or combinations of devices. In general, the term “computer system” can be broadly defined to encompass any device (or combination of devices) having at least one processor that executes instructions from a memory medium.

Processing Element (or Processor) – refers to various elements or combinations of elements that are capable of performing a function in a device, such as a user equipment or a cellular network device. Processing elements can include, for example: processors and associated memory, portions or circuits of individual processor cores, entire processor cores, processor arrays, circuits such as an ASIC (Application Specific Integrated Circuit), programmable hardware elements such as a field programmable gate array (FPGA), as well any of various combinations of the above.

Program – the term “program” is intended to have the full breadth of its ordinary meaning. The term “program” includes 1) a software program which can be stored in a memory and is executable by a processor or 2) a hardware configuration program useable for configuring a programmable hardware element.

Software Program – the term “software program” is intended to have the full breadth of its ordinary meaning, and includes any type of program instructions, code, script and/or data, or combinations thereof, that can be stored in a memory medium and executed by a processor. Exemplary software programs include programs written in text-based programming languages, such as C, C++, Pascal, Fortran, Cobol, Java, assembly language, etc.; graphical programs (programs written in graphical programming languages); assembly language programs; programs that have been compiled to machine language; scripts; and other types of executable software. A software program can comprise two or more software programs that interoperate in some manner.

Hardware Configuration Program – a program, e.g., a netlist or bit file, that can be used to program or configure a programmable hardware element.

Graphical Program – A program comprising a plurality of interconnected nodes or icons, where the plurality of interconnected nodes or icons visually indicate functionality of the program. Can also be referred to as a Virtual Instrument (VI).

Data Flow Graphical Program (or Data Flow Diagram) – A graphical program or diagram comprising a plurality of interconnected nodes, wherein the connections between the nodes indicate that data produced by one node is used by another node. Can also be referred to as a Virtual Instrument (VI).

Graphical User Interface – this term is intended to have the full breadth of its ordinary meaning. The term “graphical user interface” is often abbreviated to “GUI”. A GUI can comprise only one or more input GUI elements, only one or more output GUI elements, or both input and output GUI elements. Can also be referred to as a Virtual Instrument (VI).

The following provides examples of various aspects of GUIs. The following examples and discussion are not intended to limit the ordinary meaning of GUI, but rather provide examples of what the term “graphical user interface” encompasses:

A GUI can comprise a single window, panel, or dialog box having one or more GUI Elements, or can comprise a plurality of individual GUI Elements (or individual windows each having one or more GUI Elements), wherein the individual GUI Elements or windows can optionally be tiled together.

Graphical User Interface Element – an element of a graphical user interface, such as for providing input or displaying output. Exemplary graphical user interface elements include input controls and output indicators.

Automatically – refers to an action or operation performed by a computer system (e.g., software executed by the computer system) or device (e.g., circuitry, programmable hardware elements, ASICs, etc.), without user input directly specifying or performing the action or operation. Thus, the term “automatically” is in contrast to an operation being manually performed or specified by the user, where the user provides input to directly perform the operation. An automatic procedure can be initiated by input provided by the user, but the subsequent actions that are performed “automatically” are not specified by the user, i.e., are not performed “manually”, where the user specifies each action to perform. For example, a user filling out an electronic form by selecting each field and providing input specifying information (e.g., by typing information, selecting check boxes, radio selections, etc.) is filling out the form manually, even though the computer system must update the form in response to the user actions. The form can be automatically filled out by the computer system where the computer system (e.g., software executing on the computer system) analyzes the fields of the form and fills in the form without any user input specifying the answers to the fields. As indicated above, the user can invoke the automatic filling of the form, but is not involved in the actual filling of the form (e.g., the user is not manually specifying answers to fields but rather they are being automatically completed). The present specification provides various examples of operations being automatically performed in response to actions the user has taken.

Approximately – refers to a value that is almost correct or exact. For example, approximately can refer to a value that is within 1 to 10 percent of the exact (or desired) value. It should be noted, however, that the actual threshold value (or tolerance) can be application dependent. For example, in some embodiments, “approximately” can mean within 0.1% of some specified or desired value, while in various other embodiments, the threshold can be, for example, 2%, 3%, 5%, and so forth, as desired or as required by the particular application.

Concurrent – refers to parallel execution or performance, where tasks, processes, or programs are performed in an at least partially overlapping manner. For example, concurrency can be implemented using “strong” or strict parallelism, where tasks are performed (at least partially) in parallel on respective computational elements, or using “weak parallelism”, where the tasks are performed in an interleaved manner, e.g., by time multiplexing of execution threads.

Various components can be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors can be configured to electrically connect a module to another module, even when the two modules are not connected). In some contexts, “configured to” can be a broad recitation of structure generally meaning “having circuitry that” performs the task or tasks during operation. As such, the component can be configured to perform the task even when the component is not currently on. In general, the circuitry that forms the structure corresponding to “configured to” can include hardware circuits.

Various components can be described as performing a task or tasks, for convenience in the description. Such descriptions should be interpreted as including the phrase “configured to.” Reciting a component that is configured to perform one or more tasks is expressly intended not to invoke 35 U.S.C. § 112(f) interpretation for that component.

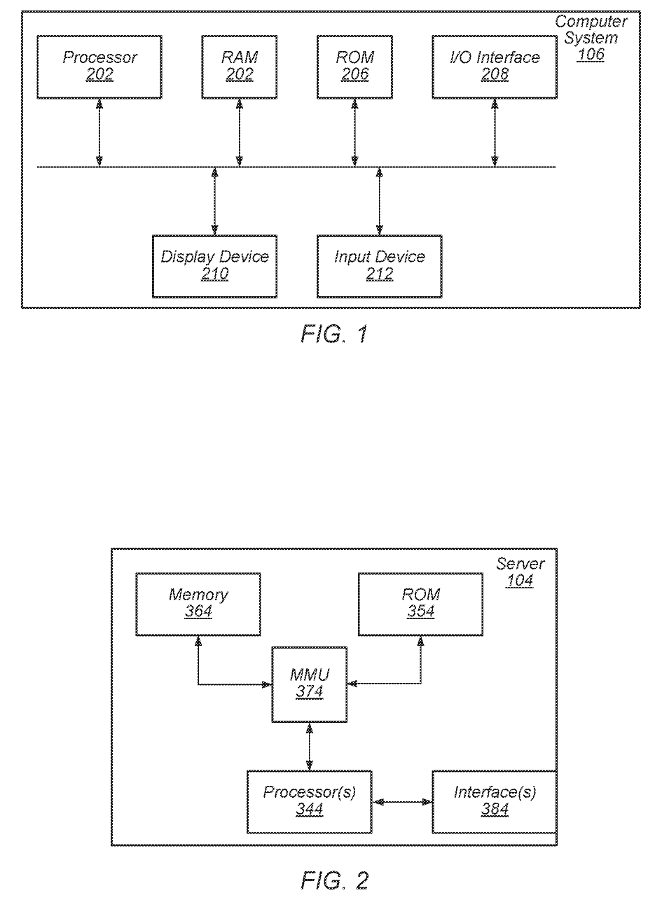

### Figure 1: Computer System

FIG. 1 illustrates a computer system 106 that can include a processor 202, random access memory (RAM) 204, nonvolatile memory 206, a display device 210, an input device 212 and an I/O interface 208 for coupling to sensors. For example, the computer system 106 can include hardware and software components for implementing or supporting implementation of features described herein. The processor 202 can be configured to implement or support implementation of part or all of the methods described herein, e.g., by executing program instructions stored on a memory medium (e.g., a non-transitory computer-readable memory medium). Alternatively, the processor 202 can be configured as a programmable hardware element, such as an FPGA (Field Programmable Gate Array), or as an ASIC (Application Specific Integrated Circuit), or a combination thereof. Alternatively (or in addition) the processor 202, in conjunction with one or more of the other components 204, 206, 208, 210, and/or 212 can be configured to implement or support implementation of part or all of the features described herein.

In addition, as described herein, processor(s) 202 can be comprised of one or more processing elements. In other words, one or more processing elements can be included in processor(s) 202. Thus, processor(s) 202 can include one or more integrated circuits (ICs) that are configured to perform the functions of processor(s) 202. In addition, each integrated circuit can include circuitry (e.g., first circuitry, second circuitry, etc.) configured to perform the functions of processor(s) 202.

As shown, the computer system 106 can include a processor that is coupled to a random access memory (RAM) and a nonvolatile memory. The computer system 106 can also include user interface elements for receiving user input and a display device for presenting output. For example, the user interface elements can include any of various elements, such as a display (which can be a touchscreen display), a keyboard (which can be a discrete keyboard or can be implemented as part of a touchscreen display), a mouse, a microphone and/or speakers, one or more cameras, one or more buttons, and/or any of various other elements capable of providing information to a user and/or receiving or interpreting user input. The computer system 106 can also include an Input/Output (I/O) interface that can be communicatively coupled (e.g., locally via a system bus, or remotely via a network and/or serial interface) to various hardware elements (e.g., such as FPGAs, data acquisition boards, controllers, and the like).

### Figure 2: Server

FIG. 2 illustrates an example block diagram of a server 104, according to some embodiments. It is noted that the server of FIG. 2 is merely one example of a possible server. As shown, the server 104 can include processor(s) 344 which can execute program instructions for the server 104. The processor(s) 344 can also be coupled to memory management unit (MMU) 374, which can be configured to receive addresses from the processor(s) 344 and translate those addresses to locations in memory (e.g., memory 364 and read only memory (ROM) 354) or to other circuits or devices.

The server 104 can be configured to provide a plurality of devices, such as computer system 106, access to various data acquisition (DAQ) devices, e.g., via interface 384. Note that in some instances, interface 384 can include one or more interfaces 384. In such instances, a first interface can be a network interface, e.g., the server 104 can be accessed via a radio access network via interface 384, such as a 5G New Radio (5G NR) radio access network and/or via a local area network (LAN), e.g., via an ethernet and/or Wi-Fi connection (e.g., supported by interface 384). Further, in such instances, an additional interfaces of the interface 384 can include one or more bus interfaces (e.g., and/or combinations of one or more bus interfaces). The one or more bus interfaces can include one or more universal serial bus (USB) interfaces, one or more a peripheral component interconnect (PCI) interfaces, one or more PCI express (PCIe) interfaces, one or more PCI extension for instrumentation (PXI) interfaces, and/or one or more PXI express (PXIe) interfaces, among other types of bus interfaces.

As described further subsequently herein, the server 104 can include hardware and software components for implementing or supporting implementation of features described herein. The processor 344 of the server 104 can be configured to implement or support implementation of part or all of the methods described herein, e.g., by executing program instructions stored on a memory medium (e.g., a non-transitory computer-readable memory medium). Alternatively, the processor 344 can be configured as a programmable hardware element, such as an FPGA (Field Programmable Gate Array), or as an ASIC (Application Specific Integrated Circuit), or a combination thereof. Alternatively (or in addition) the processor 344 of the server 104, in conjunction with one or more of the other components 354, 364, and/or 374 can be configured to implement or support implementation of part or all of the features described herein.

In addition, as described herein, processor(s) 344 can be comprised of one or more processing elements. In other words, one or more processing elements can be included in processor(s) 344. Thus, processor(s) 344 can include one or more integrated circuits (ICs) that are configured to perform the functions of processor(s) 344. In addition, each integrated circuit can include circuitry (e.g., first circuitry, second circuitry, etc.) configured to perform the functions of processor(s) 344.

### Reading/Writing Register Values of a DUT

Currently, writing values to device under test (DUT) registers is a common requirement in semiconductor and other production and validation tests. Generally, this is achieved by hand-coding digital patterns and waveforms to write specified values to specific registers based on a protocol supported by the DUT. Hand-coding digital patterns and waveforms for each DUT and for each set of registers of each DUT can be cumbersome, error-prone, and difficult to deploy and debug.

In some cases, a digital pattern editor (DPE), e.g., a software environment that allows users to interact with digital hardware, can include or support a mechanism to allow a user to define a DUT's register-map. The DPE can also be used by a user to read register values as well as to write register value to the DUT's registers using popular protocols such as I2C, SPI, RFFE-MIPI, and so forth. In addition, the DPE can be used to communicate with DUTs that use their own custom protocols. Such communications within the DPE can be achieved using template digital patterns to read from and write to the DUT’s registers. However, even using such templates, often defined and created by digital engineers conversant with the DUT's communication protocol can be cumbersome, error-prone, and difficult to deploy and debug. Therefore, improvements are desirable.

Embodiments described herein provide systems, methods, and mechanisms for reading (e.g., for verification) and writing register values to a register of a device under test (DUT). For example, embodiments described herein can leverage a register-map and write template pattern of a DUT (e.g., a DPE register-map and write template pattern and/or read template pattern of the DUT) to generate a digital pattern that can be used to write specified values to specified fields and/or to verify that specified fields have specific values. In some instances, a user, e.g., via a user interface (UI) of a DPE, can specify registers and/or register fields (e.g., a combination of bits in one or more registers) and corresponding values, e.g., in a table-view of the registers and/or register fields presented via the UI of the DPE. Further, this inputted information can be combined with an associated register-map and write template pattern and/or read template pattern to generate an output pattern. The output pattern can be considered a flat pattern. In other words, the output pattern does not use loops or jumps. In addition, the output pattern does not use source waveforms or capture waveforms; instead, the output pattern can be specified register addresses and corresponding values. In other words, the specified register addresses and corresponding values can be “hard coded” in the output pattern. Additionally, the output pattern can include comments in appropriate vectors indicating the registers and fields being written, their addresses and values, and the types of hard-coded protocol bits. The output pattern can then be deployed to a DUT, e.g., to set values of specified registers and/or register fields. Additionally, and/or alternatively, the output pattern can then be used to verify values of specified registers and/or register fields of the DUT, e.g., via a comparison of the output pattern to values read from specified registers and/or register fields of the DUT. Such a scheme can ease deployment in production tests as there is no waveform dependency while also allowing for ease in debugging read and/or write operations with output pattern when compared to debugging patterns (template or otherwise) that use waveforms.

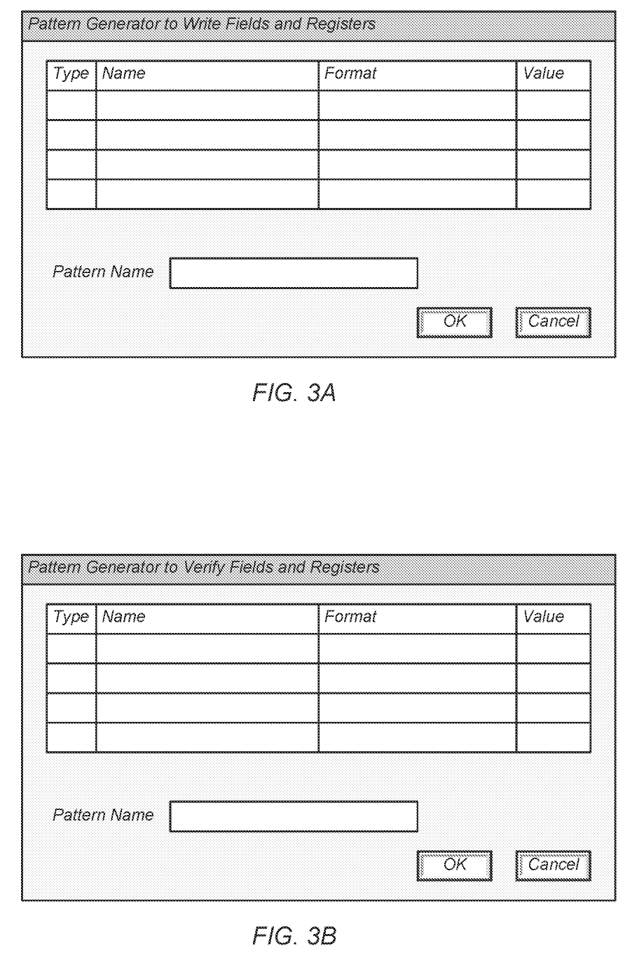

For example, FIGS. 3A and 3B illustrate examples of possible user interfaces for specifying values to generate an output pattern, according to some embodiments. In particular, FIG. 3A illustrates an example of a possible user interface for specifying values to generate an output pattern to write to one or more specified registers and/or one or more register fields of a DUT and FIG. 3B illustrates an example of a possible user interface for specifying values to generate an output pattern to verify values of one or more specified registers and/or one or more register fields of a DUT.

As shown in FIG. 3A, an input table for generating an output pattern to write to a DUT, as presented in the user interface (UI), can include a type field, a name field, a format field, and a value field. The type field can indicate whether a value is associated with a register of the DUT or a register field of the DUT. The name field can indicate a name associated with the value, e.g., such as a name of a register of the DUT or a name of a register field of the DUT. The format field can indicate a format associated with the value, e.g., such as a format of the value (e.g., hexadecimal, binary, integer, enumeration, and so forth) or a description of the value (e.g., such as operational mode, oversampling factor, oversampling mode, sampling factor, sampling mode, and so forth). The value field can indicate a value to write to the register or register field of the DUT, e.g., in terms of the format. In addition, the UI can include a field to name the output pattern associated with values from the input table. Further, the UI can include an “OK” button which saves the values, including the name of the output pattern, to memory, and a “Cancel” button which exits out of the UI without saving the values, including the name of the output pattern.

As shown in FIG. 3B, an input table for generating an output pattern to verify values of a DUT, as presented in the user interface (UI), can include a type field, a name field, a format field, and a value field. The type field can indicate whether a value is associated with a register of the DUT or a register field of the DUT. The name field can indicate a name associated with the value, e.g., such as a name of a register of the DUT or a name of a register field of the DUT. The format field can indicate a format associated with the value, e.g., such as a format of the value (e.g., hexadecimal, binary, integer, enumeration, and so forth) or a description of the value (e.g., such as operational mode, oversampling factor, oversampling mode, sampling factor, sampling mode, and so forth). The value field can indicate a value to read and verify of the register or register field of the DUT, e.g., in terms of the format. In addition, the UI can include a field to name the output pattern associated with values from the input table. Further, the UI can include an “OK” button which saves the values, including the name of the output pattern, to memory, and a “Cancel” button which exits out of the UI without saving the values, including the name of the output pattern.

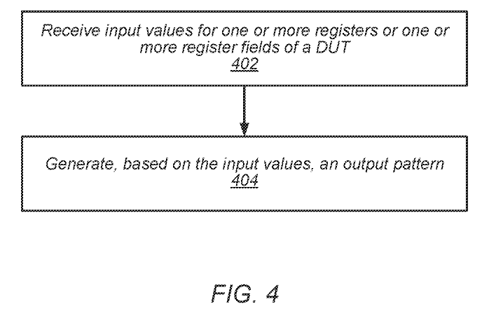

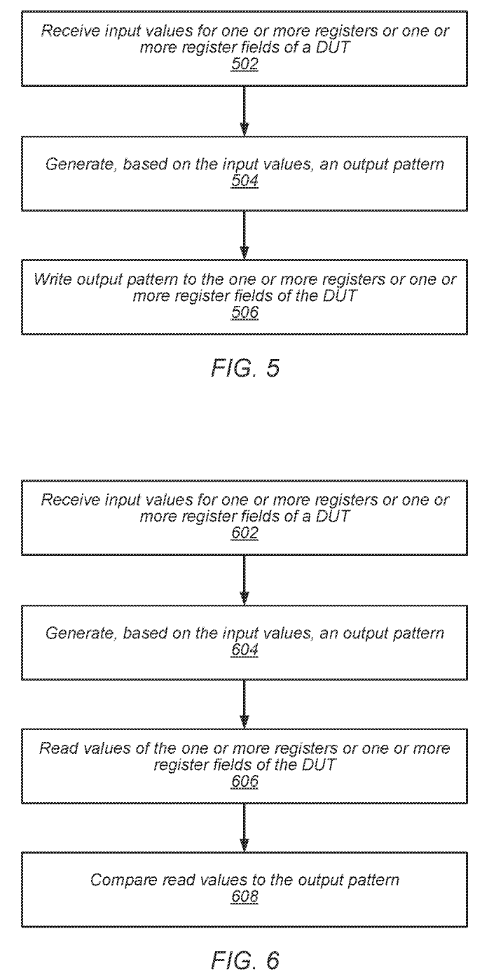

FIGS. 4, 5, and 6 illustrate block diagrams of examples of methods for digital pattern generation according to embodiments described herein. In particular, FIG. 4 illustrates a block diagram of an example of a method for DUT register pattern generation, FIG. 5 illustrates a block diagram of an example of a method for writing a generated DUT register pattern to a DUT, and FIG. 6 illustrates a block diagram of an example of a method for verifying a DUT register pattern. The methods shown in FIGS. 4, 5, and 6 can be used in conjunction with any of the systems, methods, or devices shown in the Figures, among other devices. In various embodiments, some of the elements shown can be performed concurrently, in a different order than shown, or can be omitted. Additional elements can also be performed as desired. Turning to FIGURE, as shown, this method can operate as follows.

At 402, a system, such as computer system 106 and/or server 104, can receive at least one input value for a register or register field of a DUT. In some instances, the at least one input value can include a plurality of input values, where each input value is associated with a register or register field of a DUT. In other words, the DUT can include one or more registers and/or one or more register fields and the at least one input value can include one or more values, where each value of the one or more values corresponds to a register or register field of the DUT. The at least one input value can, in some instances, be an array. The array can include one or more fields. The one or more fields can include a type field, a name field, a format field, and a value field. The type field can indicate whether the at least one input value is associated with a register of the DUT or a register field of the DUT. The name field can indicate a name associated with the at least one input value, e.g., such as a name of a register of the DUT or a name of a register field of the DUT. The format field can indicate a format associated with the at least one input value, e.g., such as a format of the value (e.g., hexadecimal, binary, integer, enumeration, and so forth) or a description of the value (e.g., such as operational mode, oversampling factor, oversampling mode, sampling factor, sampling mode, and so forth). The value field can indicate the at least one input value of the register or register field of the DUT, e.g., in terms of the format. In some instances, the at least one input value can include a plurality of arrays, where each array corresponds to a register or register field of the DUT. In some instances, the at least one input value can be received via a user interface (UI) that includes a table with one or more fields corresponding to the one or more fields of the array. In such instances, each row of the table can correspond to an array and each column of the table can correspond to a field.

At 404, the system can generate an output pattern, e.g., based on the at least one input value. In some instances, the output pattern can be further based on a register-map and write template pattern and/or read template pattern associated with the DUT. The output pattern can be a digital pattern, and, in at least some instances, the output pattern can be a flat pattern. In other words, the output pattern can be generated based, at least in part on, specified register addresses and corresponding values received as the at least one input value. In some instances, the output pattern can include parity bits and/or other information necessary to comply with a particular communication protocol associated with the DUT. In some instances, the output pattern can include comments in appropriate vectors indicating one or more registers and/or register fields, a corresponding address, a corresponding value, and/or one or more types of hard-coded protocol bits in the output pattern.

In some instances, the system can then write (or deploy) the output pattern to the DUT. In other words, the at least one input value can be written (or deployed) to a corresponding register or register field of the DUT. In cases in which the at least one input value is an array or plurality of arrays, the output pattern can be written (or deployed) to corresponding registers and/or register fields of the DUT. Note that writing (or deploying) the output pattern can include sending the output pattern to the DUT over a communication connection with the DUT and/or via a relaying system (e.g., such as an embedded system in communication with the system and the DUT).

In some instances, the system can then read the register or register field of the DUT corresponding to the at least one input value. In cases in which the at least one input value is an array or plurality of arrays, the system can read corresponding registers and/or register fields of the DUT. Note that reading the register(s) and/or register field(s) can include reading bits of the register(s) and/or register field(s). In some instances, certain value bits of the register(s) and/or register field(s) can be masked (e.g., ignored) so that only most significant bits are read. In other words, the certain bits can include most significant bits of the register(s) or register field(s) and exclude one or more least significant bits of the register(s) or register field(s). Further, the system can compare the output pattern to the read register(s) and/or register field(s). For example, when the output pattern matches the read register(s) and/or register field(s), the system can confirm and/or verify values of the register(s) and/or register field(s).

Turning to FIG. 5, as shown, this method can operate as follows.

At 502, a system, such as computer system 106 and/or server 104, can receive at least one input value for a register or register field of a DUT. In some instances, the at least one input value can include a plurality of input values, where each input value is associated with a register or register field of a DUT. In other words, the DUT can include one or more registers and/or one or more register fields and the at least one input value can include one or more values, where each value of the one or more values corresponds to a register or register field of the DUT. The at least one input value can, in some instances, be an array. The array can include one or more fields. The one or more fields can include a type field, a name field, a format field, and a value field. The type field can indicate whether the at least one input value is associated with a register of the DUT or a register field of the DUT. The name field can indicate a name associated with the at least one input value, e.g., such as a name of a register of the DUT or a name of a register field of the DUT. The format field can indicate a format associated with the at least one input value, e.g., such as a format of the value (e.g., hexadecimal, binary, integer, enumeration, and so forth) or a description of the value (e.g., such as operational mode, oversampling factor, oversampling mode, sampling factor, sampling mode, and so forth). The value field can indicate the at least one input value of the register or register field of the DUT, e.g., in terms of the format. In some instances, the at least one input value can include a plurality of arrays, where each array corresponds to a register or register field of the DUT. In some instances, the at least one input value can be received via a user interface (UI) that includes a table with one or more fields corresponding to the one or more fields of the array. In such instances, each row of the table can correspond to an array and each column of the table can correspond to a field.

At 504, the system can generate an output pattern, e.g., based on the at least one input value. In some instances, the output pattern can be further based on a register-map and write template pattern associated with the DUT. The output pattern can be a digital pattern, and, in at least some instances, the output pattern can be a flat pattern. In other words, the output pattern can be generated based, at least in part on, specified register addresses and corresponding values received as the at least one input value. In some instances, the output pattern can include parity bits and/or other information necessary to comply with a particular communication protocol associated with the DUT. In some instances, the output pattern can include comments in appropriate vectors indicating one or more registers and/or register fields, a corresponding address, a corresponding value, and/or one or more types of hard-coded protocol bits in the output pattern.

At 506, the system can then write (or deploy) the output pattern to the DUT. In other words, the at least one input value can be written (or deployed) to a corresponding register or register field of the DUT. In cases in which the at least one input value is an array or plurality of arrays, the output pattern can be written (or deployed) to corresponding registers and/or register fields of the DUT. Note that writing (or deploying) the output pattern can include sending the output pattern to the DUT over a communication connection with the DUT and/or via a relaying system (e.g., such as an embedded system in communication with the system and the DUT).

Turning to FIG. 6, as shown, this method can operate as follows.

At 602, a system, such as computer system 106 and/or server 104, can receive at least one input value for a register or register field of a DUT. In some instances, the at least one input value can include a plurality of input values, where each input value is associated with a register or register field of a DUT. In other words, the DUT can include one or more registers and/or one or more register fields and the at least one input value can include one or more values, where each value of the one or more values corresponds to a register or register field of the DUT. The at least one input value can, in some instances, be an array. The array can include one or more fields. The one or more fields can include a type field, a name field, a format field, and a value field. The type field can indicate whether the at least one input value is associated with a register of the DUT or a register field of the DUT. The name field can indicate a name associated with the at least one input value, e.g., such as a name of a register of the DUT or a name of a register field of the DUT. The format field can indicate a format associated with the at least one input value, e.g., such as a format of the value (e.g., hexadecimal, binary, integer, enumeration, and so forth) or a description of the value (e.g., such as operational mode, oversampling factor, oversampling mode, sampling factor, sampling mode, and so forth). The value field can indicate the at least one input value of the register or register field of the DUT, e.g., in terms of the format. In some instances, the at least one input value can include a plurality of arrays, where each array corresponds to a register or register field of the DUT. In some instances, the at least one input value can be received via a user interface (UI) that includes a table with one or more fields corresponding to the one or more fields of the array. In such instances, each row of the table can correspond to an array and each column of the table can correspond to a field.

At 604, the system can generate an output pattern, e.g., based on the at least one input value. In some instances, the output pattern can be further based on a register-map and read template pattern associated with the DUT. The output pattern can be a digital pattern, and, in at least some instances, the output pattern can be a flat pattern. In other words, the output pattern can be generated based, at least in part on, specified register addresses and corresponding values expected as the at least one input value. In some instances, the output pattern can include parity bits and/or other information necessary to comply with a particular communication protocol associated with the DUT. In some instances, the output pattern can include comments in appropriate vectors indicating one or more registers and/or register fields, a corresponding address, a corresponding value, and/or one or more types of hard-coded protocol bits in the output pattern.

At 606, the system can read the register or register field of the DUT corresponding to the at least one input value. In cases in which the at least one input value is an array or plurality of arrays, the system can read corresponding registers and/or register fields of the DUT. Note that reading the register(s) and/or register field(s) can include reading bits of the register(s) and/or register field(s). In some instances, certain value bits of the register(s) and/or register field(s) can be masked (e.g., ignored) so that only most significant bits are read. In other words, the certain bits can include most significant bits of the register(s) or register field(s) and exclude one or more least significant bits of the register(s) or register field(s).

At 608, the system can compare the output pattern to the read register(s) and/or register field(s). For example, when the output pattern matches the read register(s) and/or register field(s), the system can confirm and/or verify values of the register(s) and/or register field(s).

Embodiments of the present disclosure can be realized in any of various forms. For example, some embodiments can be realized as a computer-implemented method, a computer-readable memory medium, or a computer system. Other embodiments can be realized using one or more custom-designed hardware devices such as ASICs. Still other embodiments can be realized using one or more programmable hardware elements such as FPGAs.

In some embodiments, a non-transitory computer-readable memory medium can be configured so that it stores program instructions and/or data, where the program instructions, if executed by a computer system, cause the computer system to perform a method, e.g., any of the method embodiments described herein, or, any combination of the method embodiments described herein, or, any subset of any of the method embodiments described herein, or, any combination of such subsets.

In some embodiments, a device (e.g., a computer system 106) can be configured to include a processor (or a set of processors) and a memory medium, where the memory medium stores program instructions, where the processor is configured to read and execute the program instructions from the memory medium, where the program instructions are executable to implement any of the various method embodiments described herein (or, any combination of the method embodiments described herein, or, any subset of any of the method embodiments described herein, or, any combination of such subsets). The device can be realized in any of various forms.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A method for digital pattern generation, comprising:
receiving at least one input value for a register or register field of a device under test (DUT); and
generating an output pattern based, at least in part, on the at least one input value for the register or register field of the DUT.

2. The method of claim 1,
wherein the output pattern is further based, at least in part, on a register-map associated with the DUT and at least one of a write template pattern associated with the DUT or read template pattern associated with the DUT.

3. The method of claim 1,
wherein the output pattern comprises a flat pattern.

4. The method of claim 1,
wherein the at least one input value includes a plurality of input values, and wherein each input value is associated with a register or register field of the DUT.

5. The method of claim 1,
wherein the at least one input value includes an array, wherein the array includes one or more fields, and wherein the one or more fields comprise a type field, a name field, a format field, and a value field.

6. The method of claim 5,
wherein the type field indicates whether the at least one input value is associated with a register of the DUT or a register field of the DUT, wherein the name field indicates a name associated with the at least one input value, wherein the format field indicates a format associated with the at least one input value, and wherein the value field indicates the at least one input value of the register or register field of the DUT.

7. The method of claim 1,
wherein the at least one input value includes a plurality of arrays, wherein each array corresponds to a register or register field of the DUT.

8. A non-transitory computer-readable memory medium storing program instructions which, when executed by a processor, are configured to cause a computing device to:
receive, via a user interface (UI) executed by the processor, at least one input value for a register or register field of a device under test (DUT); and
generate an output pattern based, at least in part, on the at least one input value for the register or register field of the DUT.

9. The non-transitory computer readable memory medium of claim 8,
wherein the at least one input value comprises a plurality of arrays, each array comprising one or more fields, and wherein the UI includes a table, wherein a row of the table corresponds to an array, and wherein one or more columns of the table corresponds to the one or more fields of the array.

10. The non-transitory computer readable memory medium of claim 8,
wherein the output pattern is further based, at least in part, on specified register addresses and corresponding values received as the at least one input value.

11. The non-transitory computer readable memory medium of claim 8,
wherein the output pattern includes comments in appropriate vectors indicating one or more registers and/or register fields, a corresponding address, a corresponding value, and/or one or more types of hard-coded protocol bits.

12. The non-transitory computer readable memory medium of claim 8,
wherein the program instructions are further executable by the processor to cause the computing device to:
deploy the output pattern to the DUT.

13. The non-transitory computer readable memory medium of claim 12,
wherein, to deploy the output pattern to the DUT, the program instructions are further executable by the processor to cause the computing device to:
deploy the at least one input value to a corresponding register or register field of the DUT.

14. The non-transitory computer readable memory medium of claim 12,
wherein, to deploy the output pattern to the DUT, the program instructions are further executable by the processor to cause the computing device to:
deploying the output pattern to the DUT via a relay system in communication with the computing device and the DUT.

15. An apparatus, comprising:
a memory; and
at least one processor in communication with the memory and configured to cause a computing device to:
receive, via a user interface (UI) executed by the processor, at least one input value for a register or register field of a device under test (DUT); and
generate an output pattern based, at least in part, on the at least one input value for the register or register field of the DUT.

16. The apparatus of claim 15,
wherein the at least one processor is further configured to cause the computing device to:
read one or more bits of the register or register field of the DUT corresponding to the at least one input value; and
compare the output pattern to the one or more bits to verify the one or more bits.

17. The apparatus of claim 16,
wherein the one or more bits includes most significant bits of the register or register field and exclude one or more least significant bits of the register or register field.

18. The apparatus of claim 15,
wherein the output pattern is further based, at least in part, on a register-map associated with the DUT and at least one of a write template pattern associated with the DUT or read template pattern associated with the DUT.

19. The apparatus of claim 15,
wherein the output pattern comprises a flat pattern.

20. The apparatus of claim 15,
wherein the at least one input value includes a plurality of input values, and wherein each input value is associated with a register or register field of the DUT.
